(19) United States
(12) Patent Application Publication
(10) Pub. No.: US 2021/0098982 A1
(43) Pub. Date: Apr. 1, 2021

(54) SHORT-CIRCUIT PROTECTION SOLUTION FOR POWER DEVICES

(71) Applicant: Ohio State Innovation Foundation, Columbus, OH (US)

(72) Inventors: He Li, San Jose, CA (US); Xintong Lyu, Columbus, OH (US); Jin Wang, Powell, OH (US); Ke Wang, Columbus, OH (US); Diang Xing, Columbus, OH (US)

(21) Appl. No.: 17/032,202

(22) Filed: Sep. 25, 2020

Related U.S. Application Data
(60) Provisional application No. 62/906,250, filed on Sep. 26, 2019.

(51) Int. Cl. H02H 3/093; H02H 3/02; H02H 7/22; G01R 31/52; G01R 15/18; G01R 19/165

(52) U.S. Cl. CPC H02H 3/093; H02H 3/025; H02H 3/021; G01R 19/16571; G01R 31/52; G01R 15/181; H02H 7/222

(57) ABSTRACT

A reliable short-circuit protection scheme for all switching power devices is presented. This protection scheme includes an ultra-fast short-circuit detection component to quickly detect that a short-circuit may be occurring, a voltage clamping component to prevent short-term damage to the device, and a detection component that performs a system safe shutdown of the device in the event that a conventional slow over-current detection procedure verifies the short-circuit. This protection scheme can be applied to all switching devices and is especially suitable for wide bandgap (WBG) power devices which features high di/dt and high dv/dt switching capability. This protection scheme features reliable detection and protection, easy implementation, and low cost.

### CROSS-REFERENCE TO RELATED APPLICATIONS

This application claims the benefit of U.S. provisional patent application No. 62/906,250, filed on Sep. 26, 2019, and entitled “A RELIABLE SHORT-CIRCUIT PROTECTION SCHEME FOR ALL TYPES OF SWITCHING DEVICES, ESPECIALLY FOR WBG POWER DEVICES,” the disclosure of which is expressly incorporated herein by reference in its entirety.

### BACKGROUND

Semiconductor power devices have been widely used in electric vehicle, locomotive, and renewable energy applications. Power device short-circuit events are common and catastrophic issues in the field operation. Upon short-circuit events, lame amount of enemy will be generated and accumulated in the semiconductor dies. The short-circuit energy accumulation leads to high junction temperature which accelerate power device degradation and cause device failure eventually. Early detection of and quick response to die short-circuit condition become critical to prevent power device failure and ensure system safe operation.

Compared with the silicon (Si) counterparts, wide bandgap (WBG) devices offer higher temperature capability, lower on-resistance, and higher switching speed. The high switching speed can benefit converters/inverters in terms of lower switching loss, higher switching frequency, smaller volume of capacitors and magnetic components, and attendant weight/cost reduction. All these benefits make WBG power devices a replacement of Si devices. Meanwhile, the thinner and smaller size of the WBG power device dies leads to smaller thermal capacity. Special gate design of the WBG power devices leads to higher short-circuit current and more short-circuit energy. Consequently, the WBG power devices require quicker response to the short-circuit condition and shorter protection time to mitigate device degradation and prevent failure.

A simple, reliable, low cost short-circuit detection and protection solution is in demand for switching power devices.

### SUMMARY

A reliable short-circuit protection scheme for all switching power devices is provided. This protection scheme includes an ultra-fast short-circuit detection component to quickly detect that a short-circuit may be occurring, a clamping component to prevent short-term damage to the device, and a detection component that performs a system safe shutdown of the device in the event that a conventional slow over-current detection procedure verifies the short-circuit. This protection scheme can be applied to all switching devices and is especially suitable for wide bandgap (WBG) power devices which features high di/dt and high dv/dt switching capability. This protection scheme features reliable detection and protection, easy implementation, and low cost.

In an embodiment, a short-circuit protection method for a device is provided. The method includes: detecting a fault condition of the device; reducing a device channel conductivity of the device to prevent device fatal failure or alleviate device degradation due to the fault condition; confirming that the fault condition is a short-circuit condition using a slow response protection circuit; and shutting down the device sequentially and safely in response to the confirmation using a controller.

Embodiments may include some or all of the following features. Reducing the device channel conductivity may be performed by adjusting a gate status. The device may be a voltage-controlled device, and adjusting the gate status may include reducing a gate voltage to limit channel conductivity. The device may be a current-controlled device, and adjusting the gate status may include reducing a gate drive current. Adjusting the gate status may include adjusting a gate loop impedance. The method may further include when the slow response protection circuit does not confirm that the fault condition is the short-circuit condition within a predetermined period, returning a gate voltage of the device to a normal drive status. The device may be a semiconductor switching device. Detecting the fault condition of the device may include detecting the fault condition based on a direct current measurement with a responsive high frequency current transformer (HFCT). Detecting the fault condition of the device may include detecting the fault condition based on a direct current measurement with a Rogowski coil. Detecting the fault condition of the device may include detecting the fault condition based on a measurement of a common source inductance and a power loop stray inductance. Detecting the fault condition of the device may include detecting the fault condition of the device based on a measurement of a half bridge voltage between an upper device drain and a lower device source. Detecting the fault condition of the device may include detecting the fault condition of the device based on a measurement of a decoupling capacitor voltage.

In an embodiment, a system for protecting a device from a short-circuit is provided. The system includes: a detection component configured to detect a fault condition of the device; a gate clamping component configured to reduce a device channel conductivity of the device by adjusting a gate status; and a turn-off component configured to confirm the fault condition is a short-circuit condition; and shut down the device sequentially and safely.

Embodiments may include some or all of the following features. The device may be a voltage-controlled device, and the gate clamping component adjusting the gate status may include the gate clamping component reducing a gate voltage to limit channel conductivity. The device may be a current-controlled device, and the gate clamping component adjusting the gate status may include the gate clamping component reducing a gate drive current. The gate clamping component adjusting the gate status may include the gate clamping component adjusting an equivalent gate loop impedance. When the turn-off component does not confirm that the fault condition is the short-circuit condition within a predetermined period, the turn-off component may allow a gate voltage of the device to return to a normal drive status. The device may be a semiconductor switching device. The detection component configured to detect the fault condition of the device may include the detection component configured to detect the fault condition of the device using at least one of a responsive high frequency current transformer (HFCT) or a Rogowski coil. The detection component configured to detect the fault condition of the device may include the detection component configured to detect the fault condition of the device based on a common source inductance and a power loop stray inductance.

This summary is provided to introduce a selection of concepts in a simplified form that are further described below in the detailed description. This summary is not intended to identify key features or essential features of the claimed subject matter, nor is it intended to be used to limit the scope of the claimed subject matter.

### BRIEF DESCRIPTION OF THE DRAWINGS

The foregoing summary, as well as the following detailed description of illustrative embodiments, is better understood when read in conjunction with the appended drawings. For the purpose of illustrating the embodiments, there is shown in the drawings example constructions of the embodiments; however, the embodiments are not limited to the specific methods and instrumentalities disclosed. In the drawings:

FIG. 1 is an illustration of an example short-circuit detection and protection circuit;

FIG. 2 is an illustration of a method for detecting and handling fault conditions in an attached device;

FIG. 3 is an illustration of a method for detecting and handling fault conditions in an attached device; and

FIG. 4 is an illustration of an example short-circuit loop circuit that may be used to detect short-circuit fault conditions in an attached device.

### DETAILED DESCRIPTION

This description provides examples not intended to limit the scope of the appended claims. The figures generally indicate the features of the examples, where it is understood and appreciated that like reference numerals are used to refer to like elements. Reference in the specification to “one embodiment” or “an embodiment” or “an example embodiment” means that a particular feature, structure, or characteristic described is included in at least one embodiment described herein and does not imply that the feature, structure, or characteristic is present in all embodiments described herein.

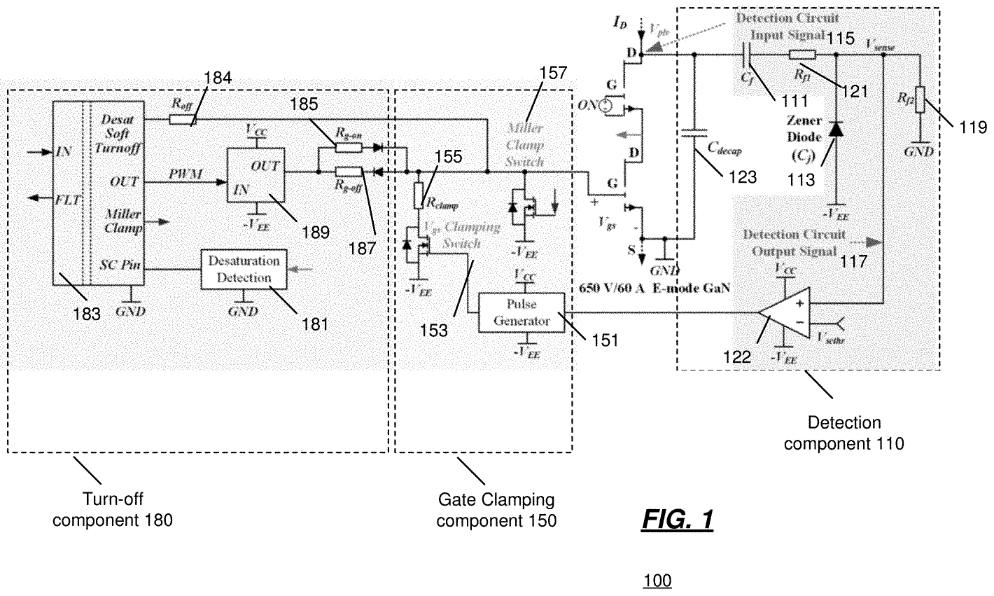

FIG. 1 is an illustration of an example short-circuit detection and protection circuit 100. As shown, the circuit 100 comprises three main components including, but not limited to, a detection component 110, a gate clamping component 120, and a turn-off component 130. The circuit 100 may be part of a half-bridge structure.

The detection component 110 may provide ultra-fast detection of a fault condition of a device attached to the circuit 100. In an embodiment, the fault condition may be a short-circuit condition on a received detection circuit input signal 115 from the device. The device may be a semiconductor device or a voltage-controlled device, for example.

As illustrated the detection component 110 includes several components including, but not limited to a capacitor C_{f} (i.e., the capacitor 111), a resistor R_{f1} (i.e., the resistor 121), a resistor R_{f2} (i.e., the resistor 119), a zener diode 113, an amplifier 122, and one or more decoupling capacitors C_{decop} (i.e., the decoupling capacitors 123). The various components may be wired as shown in FIG. 1.

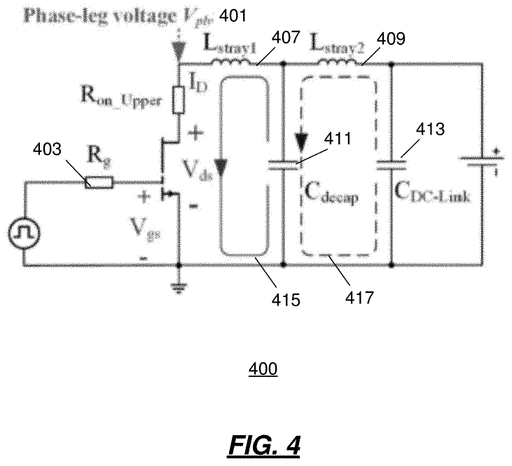

Under the short-circuit condition, the monitored phase-leg voltage (Vₚₗᵥ) from the detection circuit input signal 115 shows a sudden dip due to parasitic induction in a power loop formed by the decoupling capacitors 123 and a high di/dt. The voltage dip may be detected when V_{sence} is less than the V_{scthr} received by the amplifier 122. In response, the detection component 110 may set a trigger flag FLT that indicates that a short-circuit condition has been detected, and the amplifier 122 may begin outputting a detection circuit output signal 117 to the gate clamping component 150. Details of the short-circuit loop detection circuit of the detection component 110 are described in more detail with respect to FIG. 4.

The gate clamping component 150 may reduce the power device channel conductivity of the device in response to the detected fault condition. Reducing the power device channel conductivity may prevent a fatal device failure or may otherwise prevent device degradation.

The gate clamping component 150 may clamp the device drive voltage V_{gs} in response to the detection component 110 detecting a short-circuit condition. As shown, the gate clamping component 150 includes several components including, but not limited to a pulse generator 151, a clamping switch 153, a resistor R_{clamp} (i.e., a resistor 155), and a miller clamp switch 157.

In one embodiment, the miller clamp switch 157 is connected to a device gate terminal of the device. The resistor 155 and a device gate resistor associated with the device form a voltage divider. The voltage divider will reduce the drive voltage of the device to a lower voltage for a holding period. The holding period may be set by a user or administrator by adjusting one or more parameters associated with the pulse generator 151. This lower voltage may protect the device from failure or damage due to the short-circuit condition, or other detected fault condition.

The turn-off component 180 may provide for the safe shutdown of the device in the event that the fault condition is verified. As shown, the turn-off component 180 includes a desaturation detection circuit 181, a controller 183, a voltage regulator 189, a resistor R_{off} (i.e., the resistor 184), a resistor R_{g-on} (i.e., the resistor 185), and a resistor R_{g-off} (i.e., the resistor 187). More or fewer components may be supported.

The desaturation detection circuit 181 may be a slow detection circuit that can detect or verify the fault condition detected by the detection component 110. If the desaturation circuit 181 detects or verifies the fault condition before the expiration of the holding time, the desaturation circuit 181 may send a signal to the controller 183. In response, the controller 183 may cause the device to have a soft turn-off.

In some embodiments, the desaturation detection circuit 181 may detect a fault condition such a short-circuit when excessive on-state drain to source voltage from the device is detected. Other methods for detecting or confirming the fault condition may be used including current transformer-based overcurrent protection, current transducer-based overcurrent protection, and shunt-based overcurrent protection, Rogowski coil-based protection, and on-die temperature sensing protection.

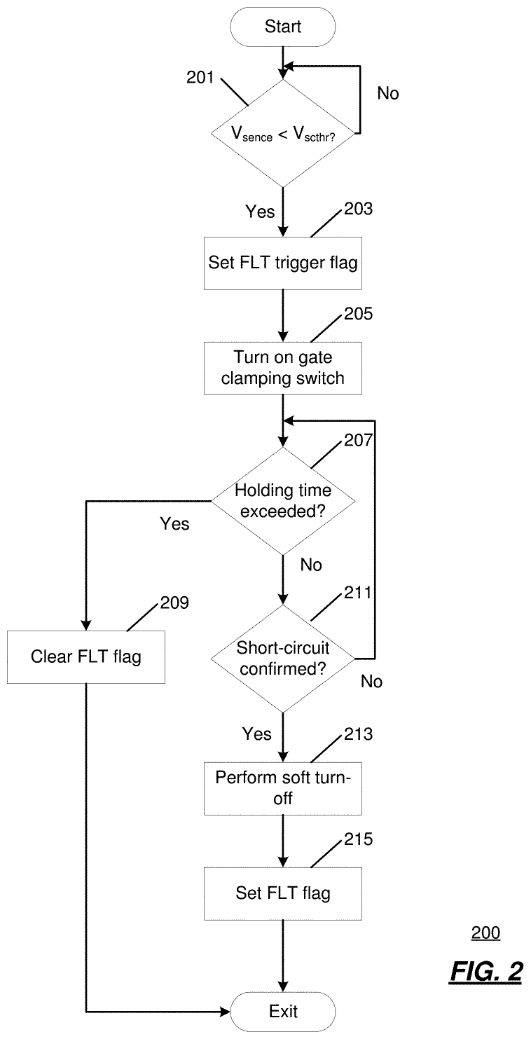

FIG. 2 is an illustration of a method for detecting and handling fault conditions. The method 200 may be performed by the circuit 100 of FIG. 1, and in particular by the detection component 110, the gate clamping component 150, and the turn-off component 180.

At 201, whether the voltage V_{sence} is lower than V_{scthr} is determined. The determination may be made by the detection component 110. The detection component 110 may include an ultra-fast detection circuit that detects fault conditions in an attached device. V_{sence} being lower than V_{scthr} may indicate such a fault condition in the attached device. The fault condition may be a short-circuit condition. The attached device may be semiconductor device. If the voltage V_{sence} is lower than V_{scthr} then the method 200 may continue to 203. Else, the method 200 may remain at 201 until the voltage V_{sence} is lower than V_{scthr}.

At 203, the FLT trigger flag may be set. The FLT trigger flag may be set by the detection component 110 in response to the detection component 110 determining a short-circuit condition. By setting the FLT trigger, the detection component 110 may have started the process through which a slow fault detection circuit (i.e., the desaturation detection circuit 181) of the turn-off component 180 confirms the detected short-circuit condition.

At 205, a gate clamping switch is turned on. The gate clamping switch may be turned on by the gate clamping component 150 in response to the FLT trigger flag being set by the detection component 110. The gate clamping switch may clamp an input voltage and/or current received by the circuit 100 from the device.

At 207, whether a holding time has exceeded is determined. The determination may be made by the gate clamping component 150. The holding time may be a maximum amount of time for the gate clamping component 150 to clamp the voltage/current. The maximum time may be controlled by the pulse generator 151 and may be set by a user or administrator. If the holding time is exceeded, then the method 200 may continue at 209. Else, the method 200 may continue at 211.

At 209, the FLT flag may be cleared. The FLT flag may be cleared by the gate clamping component 150 in response to determining that the holding time has been exceeded. The holding time being exceeded without the turn-off component 180 confirming the short-circuit condition detected at 201 may indicate the detected short-circuit condition was false. After clearing the FLT flag, the method 200 may exit or may return to 201 to continue to monitor for short-circuit conditions by the detection component 110.

At 211, a whether the short-circuit is confirmed is determined. The short-circuit may be confirmed by the turn-off component 180. In some embodiments, the turn-off component 180 may confirm the short-circuit condition by the desaturation detection circuit 181 detecting excessive on-state drain to source voltage. Other methods for confirming a short-circuit condition may be used. If the short-circuit condition is confirmed, then the method may continue at 215. Else, the method 200 may return to 207 where the gate clamping component 150 may continue to determine if the holding time has been exceeded.

At 213, a soft turn-off is performed. The soft turn-off may be performed by the controller 183 of the turn-off component 180 in response to confirming the short-circuit condition. Any method for performing a soft turn-off may be used.

At 215, an FLT flag is set. The FLT flag may indicate that the short-circuit condition was verified. The FLT flag may be set by the turn-off component 180 before or after initiating the soft turn-off of the device.

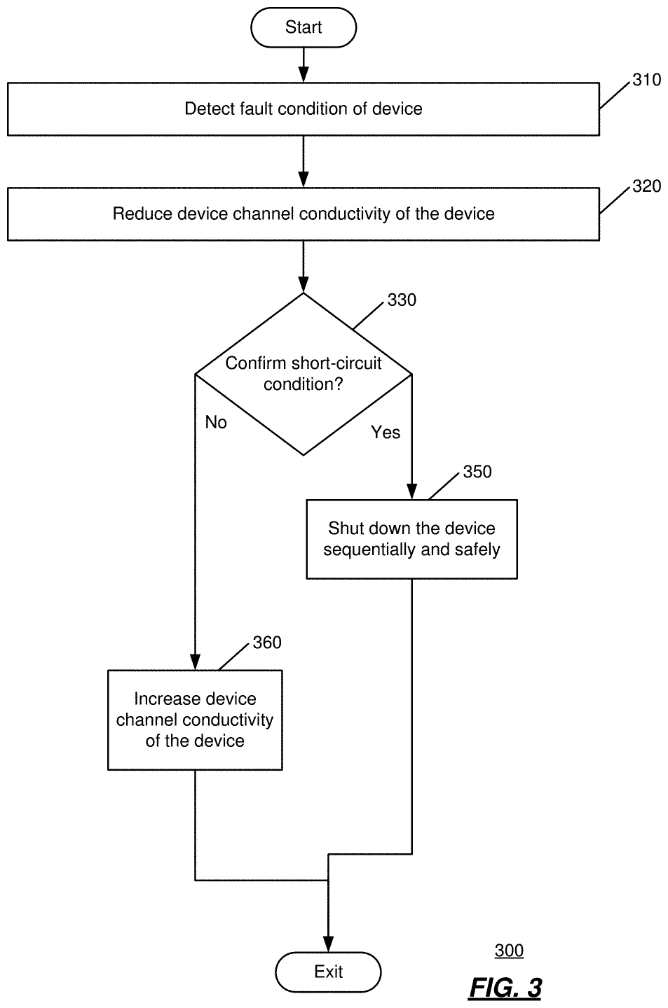

FIG. 3 is an illustration of a method for detecting and handling fault conditions such as short-circuit conditions. The method 300 may be performed by the circuit 100 of FIG. 1, and in particular by the detection component 110, the gate clamping component 150, and the turn-off component 180.

At 310, a fault condition of a device is determined. The fault condition may be for a device and may be detected by the detection component 110. The fault condition may be a short-circuit condition of the device. In some embodiment, the fault condition may be detected based on one or more of a direct current measurement of the device with a responsive high frequency current transformer (HFCT), a direct current measurement of the device with a Rogowski coil, a measurement of the device based on a common source inductance and a power loop stray inductance, a measurement of a half bridge voltage between an upper device drain and a lower device source, or a measurement of a decoupling capacitor voltage. Other methods may be used.

At 320, a device channel conductivity of the device is reduced. The device channel conductivity may be reduced by the gate clamping component 150. Reducing the device channel conductivity may help to prevent a device fatal failure and alleviate device degradation.

In some embodiments, the device channel conductivity may be reduced by the gate clamping component 150 adjusting a gate status by reducing a gate voltage or adjusting an equivalent gate loop impedance. If the device is a current controlled device, the device channel conductivity may be reduced by reducing a gate drive current. Other methods may be used.

At 330, whether the short-circuit condition is confirmed is determined. Whether the short-circuit is confirmed may be determined by a slow fault detection circuit that is part of the turn-off component 180. The confirmation of the short-circuit condition may take place within a predetermined period (i.e., holding time). If the short-circuit is confirmed within the holding time, the method 300 may continue to 350. Else, the method 300 may continue to 360.

At 350, the device is shut down securely and safely. The device may be shut down by the controller 183 of the turn-off component 180. Any method for safe and secure shut down may be used. After shutting the device down the method 300 may exit.

At 360, the device channel conductivity of the device is increased. The device channel conductivity may be increased by the gate clamping component 150. Depending on how the device channel conductivity was reduced, the gate clamping component 150 may allow the device channel conductivity to return to the same level that it was at before the fault condition of the device was detected at 310. After increasing the channel conductivity, the method 300 may exit or may return to 310 to detect another fault condition of the device.

FIG. 4 is an illustration of an example short-circuit loop circuit 400 that may be used to detect short-circuit fault conditions in an attached device. The circuit 400 may be part of the detection component 110 described above with respect to FIG. 1.

As shown, the circuit 400 includes several components including, but not limited to a resistor R_{g} (i.e., the resistor 403), a plurality of decoupling capacitors C_{decap} (i.e., the decoupling capacitors 411), and a dc-link capacitor bank C_{DC-Link} (i.e., the dc-link capacitors 413).

An inductance L_{stray1} (i.e., the inductance 407) represents a stray inductance of a current conduction loop formed by the decoupling capacitors 411 and a phase-leg voltage Vₚₗᵥ 401 of the associated devices. The current conduction loop is represented in FIG. 4 as the loop 415. The inductance 407 may incorporate stray inductances from the device, any printed circuit board traces, and an equivalent series inductance of the decoupling capacitors 411.

An inductance L_{stray2} (i.e., the inductance 409) represents a stray induction of a loop formed by the decoupling capacitors 411 and the dc-link capacitors 413. The loop is represented in FIG. 4 as the loop 417.

In the circuit 400, when the associated device experiences a fault condition, such as a short-circuit condition, phase-leg voltage Vₚₗᵥ 401 first experiences a quick voltage dip and then oscillates. Accordingly, the behavior of the phase-leg voltage Vₚₗᵥ 401 of the circuit 400 may be used to detect short-circuit conditions by the detection component 110.

As used herein, the singular form “a,” “an,” and “the” include plural references unless the context clearly dictates otherwise.

As used herein, the terms “can,” “may,” “optionally,” “can optionally,” and “may optionally” are used interchangeably and are meant to include cases in which the condition occurs as well as cases in which the condition does not occur.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed.

It should be understood that the various techniques described herein may be implemented in connection with hardware components or software components or, where appropriate, with a combination of both. Illustrative types of hardware components that can be used include Field-Programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc. The methods and apparatus of the presently disclosed subject matter, or certain aspects or portions thereof, may take the form of program code (i.e., instructions) embodied in tangible media, such as floppy diskettes, CD-ROMs, hard drives, or any other machine-readable storage medium where, when the program code is loaded into and executed by a machine, such as a computer, the machine becomes an apparatus for practicing the presently disclosed subject matter.

Although exemplary implementations may refer to utilizing aspects of the presently disclosed subject matter in the context of one or more stand-alone computer systems, the subject matter is not so limited, but rather may be implemented in connection with any computing environment, such as a network or distributed computing environment. Still further, aspects of the presently disclosed subject matter may be implemented in or across a plurality of processing chips or devices, and storage may similarly be effected across a plurality of devices. Such devices might include personal computers, network servers, and handheld devices, for example.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A short-circuit protection method for a device, the method comprising:
detecting a fault condition of the device;
reducing a device channel conductivity of the device to prevent device fatal failure or alleviate device degradation due to the fault condition;
confirming that the fault condition is a short-circuit condition using a slow response protection circuit; and
shutting down the device sequentially and safely in response to the confirmation using a controller.

2. The method of claim 1, wherein reducing the device channel conductivity is performed by adjusting a gate status.

3. The method of claim 2, wherein the device is a voltage-controlled device, and wherein adjusting the gate status comprises reducing a gate voltage to limit channel conductivity.

4. The method of claim 2, wherein the device is a current-controlled device, and wherein adjusting the gate status comprises reducing a gate drive current.

5. The method of claim 2, wherein adjusting the gate status comprises adjusting a gate loop impedance.

6. The method of claim 1, further comprising when the slow response protection circuit does not confirm that the fault condition is the short-circuit condition within a predetermined period, returning a gate voltage of the device to a normal drive status.

7. The method of claim 1, wherein the device is a semiconductor switching device.

8. The method of claim 1, wherein detecting the fault condition of the device comprises detecting the fault condition based on a direct current measurement with a responsive high frequency current transformer (HFCT).

9. The method of claim 1, wherein detecting the fault condition of the device comprises detecting the fault condition based on a direct current measurement with a Rogowski coil.

10. The method of claim 1, wherein detecting the fault condition of the device comprises detecting the fault condition based on a measurement of a common source inductance and a power loop stray inductance.

11. The method of claim 1, wherein detecting the fault condition of the device comprises detecting the fault condition of the device based on a measurement of a half bridge voltage between an upper device drain and a lower device source.

12. The method of claim 1, wherein detecting the fault condition of the device comprises detecting the fault condition of the device based on a measurement of a decoupling capacitor voltage.

13. A system for protecting a device from a short-circuit, the system comprising:
a detection component configured to detect a fault condition of the device;
a gate clamping component configured to reduce a device channel conductivity of the device by adjusting a gate status; and
a turn-off component configured to confirm the fault condition is a short-circuit condition; and shut down the device sequentially and safely.

14. The system of claim 13, wherein the device is a voltage-controlled device, and wherein the gate clamping component adjusting the gate status comprises the gate clamping component reducing a gate voltage to limit channel conductivity.

15. The system of claim 13, wherein the device is a current-controlled device, and wherein the gate clamping component adjusting the gate status comprises the gate clamping component reducing a gate drive current.

16. The system of claim 13, wherein the gate clamping component adjusting the gate status comprises the gate clamping component adjusting an equivalent gate loop impedance.

17. The system of claim 16, wherein when the turn-off component does not confirm that the fault condition is the short-circuit condition within a predetermined period, the turn-off component allows a gate voltage of the device to return to a normal drive status.

18. The system of claim 13, wherein the device is a semiconductor switching device.

19. The system of claim 13, wherein the detection component configured to detect the fault condition of the device comprises the detection component configured to detect the fault condition of the device using at least one of a responsive high frequency current transformer (HFCT) or a Rogowski coil.

20. The system of claim 13, wherein the detection component configured to detect the fault condition of the device comprises the detection component configured to detect the fault condition of the device based on a common source inductance and a power loop stray inductance.
